(19) United States
(12) Patent Application Publication
(10) Pub. No.: US 2025/0300691 A1
(43) Pub. Date: Sep. 25, 2025

(54) HIGH-FREQUENCY MODULE AND COMMUNICATION DEVICE

(71) Applicant: Murata Manufacturing Co., Ltd., Kyoto-fu (JP)

(72) Inventor: Satoshi SAKITA, Nagaokakyo-shi (JP)

(73) Assignee: Murata Manufacturing Co., Ltd., Kyoto-fu (JP)

(21) Appl. No.: 19/085,620

(22) Filed: Mar. 20, 2025

(30) Foreign Application Priority Data
Mar. 22, 2024 (JP) 2024-047289

(51) Int. Cl. H04B 1/40; H03F 3/24

(52) U.S. Cl. CPC H04B 1/40; H03F 3/24; H03F 2200/451

(57) ABSTRACT

A high-frequency module includes a mounting board, a transmission component, an electronic component, and metal members. The transmission component is disposed on the mounting board. The electronic component is disposed on the mounting board, and handles a signal in a frequency band that at least partially overlaps a frequency band of a harmonic component of a transmission signal generated by the transmission component. The metal members are disposed near at least one component out of the transmission component and the electronic component, and each have an electrical length that is a half or quarter of a wavelength of the harmonic component.

### CROSS-REFERENCE TO RELATED APPLICATION

This application claims benefit of priority to Japanese Patent Application No. 2024-047289, filed Mar. 22, 2024, the entire content of which is incorporated herein by reference.

### BACKGROUND

### Technical Field

The present disclosure relates generally to a high-frequency module and a communication device, and more specifically, to a high-frequency module including a transmission component and an electronic component, and a communication device including the high-frequency system.

### Background Art

A front end module described in U.S. Patent Application Publication No. 2019/0115946 includes a module board (mounting board), an LB (Low Band) power amplifier for 3GPP standards (transmission component), and an MB (Mid Band) low-noise amplifier for 3GPP standards (electronic component). The LB power amplifier and the MB low-noise amplifier are disposed on the same module board. In this front end module, transmission of an LB transmission signal and reception of an MB reception signal may be performed simultaneously in carrier aggregation.

### SUMMARY

In the front end module described in U.S. Patent Application Publication No. 2019/0115946, the LB power amplifier and the MB low-noise amplifier may be disposed close to each other on the same module board. If the transmission of the LB transmission signal and the reception of the MB reception signal are performed simultaneously in such disposition, for example, a second or third harmonic wave (harmonic component) of the LB transmission signal is issued from the LB power amplifier to the surroundings. The issued second or third harmonic wave is superimposed as noise on the MIB reception signal flowing through the MIB low-noise amplifier. As a result, the reception sensitivity of the MIB reception signal decreases.

In view of the problem described above, the present disclosure provides a high-frequency module and a communication device in which isolation between a transmission component and an electronic component can be improved.

A high-frequency module according to one aspect of the present disclosure includes a mounting board, a transmission component, an electronic component, and a metal member. The transmission component is disposed on the mounting board. The electronic component is disposed on the mounting board, and handles a signal in a frequency band that at least partially overlaps a frequency band of a harmonic component of a transmission signal generated by the transmission component. The metal member is disposed near at least one component out of the transmission component and the electronic component, and has an electrical length that is a half or a quarter of a wavelength of the harmonic component.

A communication device according to one aspect of the present disclosure includes the high-frequency module and a signal processing circuit. The signal processing circuit is connected to the high-frequency module, and performs signal processing on a high-frequency signal.

The high-frequency module and the communication device according to the present disclosure have an advantage in that the isolation between the transmission component and the electronic component can be improved.

### BRIEF DESCRIPTION OF THE DRAWINGS

FIG. 1 is a block diagram of a high-frequency module and a communication device according to a first embodiment;

FIG. 2 is an explanatory diagram illustrating an example of disposition of main parts of the high-frequency module;

FIG. 3 is an explanatory diagram illustrating an example of disposition of main parts of a high-frequency module according to a sixth modification of the first embodiment;

FIG. 4 is an explanatory diagram illustrating an example of a circuit connected between a metal member and a ground electrode in the high-frequency module;

FIG. 5 is an explanatory diagram illustrating another example of the circuit connected between the metal member and the ground electrode in the high-frequency module;

FIG. 6 is an explanatory diagram illustrating another example of the circuit connected between the metal member and the ground electrode in the high-frequency module;

FIG. 7 is an explanatory diagram illustrating another example of the circuit connected between the metal member and the ground electrode in the high-frequency module;

FIG. 8 is an explanatory diagram illustrating a metal member of a seventh modification of the first embodiment;

FIG. 9 is an explanatory diagram illustrating a metal member of an eighth modification of the first embodiment; and

FIG. 10 is an explanatory diagram illustrating an example of disposition of main components of a high-frequency module according to a second embodiment.

### DETAILED DESCRIPTION

### First Embodiment

A high-frequency module 1 including a power amplifier and a communication device 100 according to a first embodiment are described in detail with reference to the drawings.

### BACKGROUND

In recent years, communication devices such as mobile phones have been compatible with a plurality of radio communication systems (e.g., LTE (registered trademark; Long Term Evolution), Bluetooth (registered trademark), Wi-Fi (registered trademark), NR (New Radio), and GNSS (Global Navigation Satellite System)) and their communicative frequency bands continue to expand. There is a demand to downsize the communication devices. Due to the downsizing, the spacing between a plurality of signal paths corresponding to different frequency bands and the spacing between a plurality of electronic components corresponding to different frequency bands decrease inside the communication device. Therefore, each electronic component may be affected by a harmonic component that is issued from another electronic component used in another radio communication system and is a harmonic component of a signal flowing through the other electronic component. Thus, the radio performance may decrease. For example, a harmonic component generated during Cellular LB (Low band) communication may be superimposed on a Cellular MB (Middle band) signal or a Cellular UHB (Ultra High band) signal, and the communication quality may decrease during, for example, ENDC (E-UTRAN New-radio Dual Connectivity) communication. Therefore, it is necessary to secure isolation between electronic components used in different radio communication systems.

### Overview

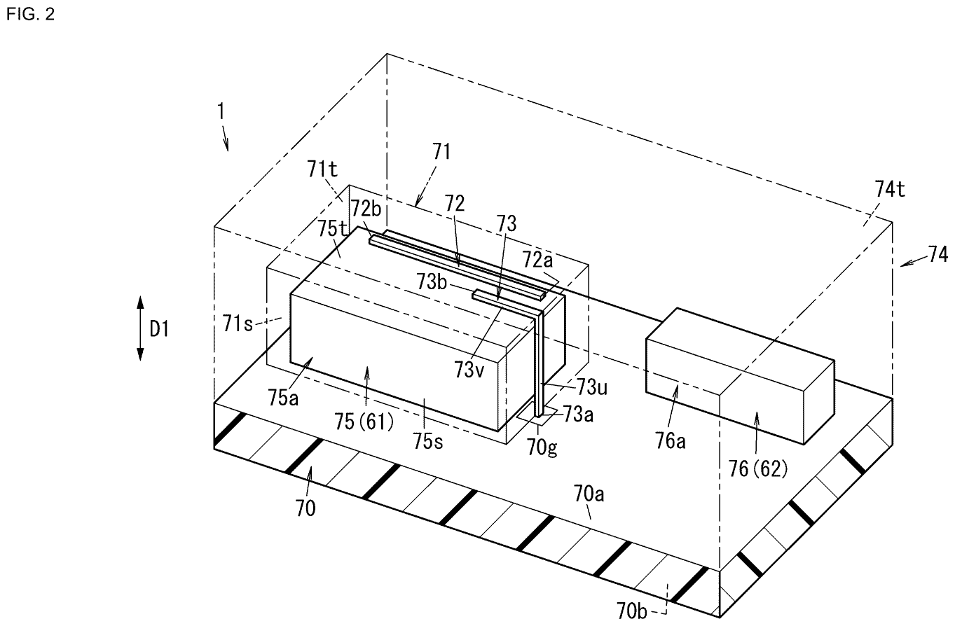

As illustrated in FIG. 2, the high-frequency module 1 according to the first embodiment includes a mounting board 70, a transmission component 75, an electronic component 76, and metal members 72 and 73. The transmission component 75 is disposed on the mounting board 70. The electronic component 76 is disposed on the mounting board 70, and handles a signal in a frequency band that at least partially overlaps a frequency band of a harmonic component of a transmission signal generated by the transmission component 75. The metal members 72 and 73 are disposed near at least one component out of the transmission component 75 and the electronic component 76 (transmission component 75 in the example of FIG. 2), and each have an electrical length that is a half or quarter of the wavelength of the harmonic component.

With this structure, the metal members 72 and 73 can improve isolation between the transmission component 75 and the electronic component 76. That is, the metal members 72 and 73 can suppress the effect of the harmonic component issued from the transmission component 75 as noise on the signal flowing through the electronic component 76.

### Structure of Communication Device

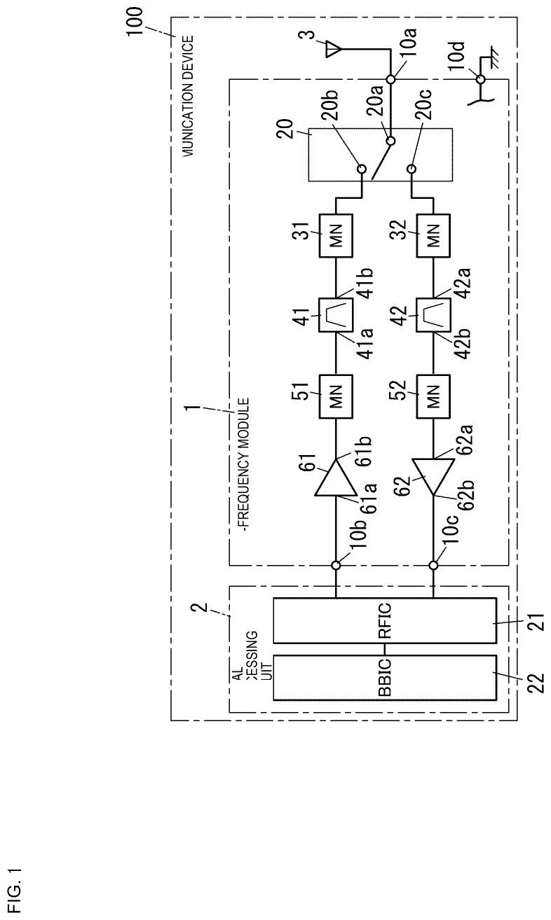

As illustrated in FIG. 1, the communication device 100 is a communication device including the high-frequency module 1. For example, the communication device 100 is a mobile terminal (e.g., a smartphone) but is not limited to the mobile terminal and may be, for example, a wearable terminal (e.g., a smart watch). The high-frequency module 1 is a module compatible with, for example, 4G (fourth generation mobile communication) standards and 5G (fifth generation mobile communication) standards. The 4G standards are, for example, 3GPP (registered trademark; Third Generation Partnership Project) or LTE standards. The 5G standards are, for example, 5G NR. The high-frequency module 1 is a module compatible with carrier aggregation and dual connectivity.

The communication device 100 further includes a signal processing circuit 2 and an antenna 3 in addition to the high-frequency module 1.

The high-frequency module 1 amplifies a reception signal (high-frequency signal) received by the antenna 3, and outputs the reception signal to the signal processing circuit 2. The high-frequency module 1 amplifies a transmission signal (high-frequency signal) output from the signal processing circuit 2, and transmits the transmission signal from the antenna 3. The high-frequency module 1 is controlled by, for example, the signal processing circuit 2.

The signal processing circuit 2 is connected to the high-frequency module 1, and performs signal processing on the reception signal output from the high-frequency module 1. The signal processing circuit 2 performs signal processing on the transmission signal to be output to the high-frequency module 1. The signal processing circuit 2 includes an RF (Radio Frequency) signal processing circuit 21 and a baseband signal processing circuit 22.

The RF signal processing circuit 21 is, for example, an RFIC (Radio Frequency Integrated Circuit), and performs signal processing on high-frequency signals (transmission signal and reception signal). The RF signal processing circuit 21 performs signal processing such as down-conversion on the reception signal output from the high-frequency module 1, and outputs the reception signal to the baseband signal processing circuit 22. The RF signal processing circuit 21 performs signal processing such as up-conversion on the transmission signal output from the baseband signal processing circuit 22, and outputs the transmission signal to the high-frequency module 1.

The baseband signal processing circuit 22 is, for example, a BBIC (Baseband Integrated Circuit). The baseband signal processing circuit 22 outputs the reception signal output from the RF signal processing circuit 21 to the outside. The output signal (reception signal) can be used, for example, as an image signal to display an image, or as an audio signal to make a telephone conversation. The baseband signal processing circuit 22 generates a transmission signal from a baseband signal (e.g., an audio signal or an image signal) input from the outside, and outputs the generated transmission signal to the RF signal processing circuit 21.

### Structure of High-frequency Module 1

The high-frequency module 1 performs communication using a plurality of different communication bands. The plurality of communication bands is, for example, an LB (Low Band), an MB (Mid Band), and an HB (High Band). As illustrated in FIG. 1, the high-frequency module 1 includes a plurality of external terminals 10a to 10d and a plurality of electronic components. In the example of FIG. 1, the plurality of electronic components includes a switch 20, matching circuits 31, 32, 51, and 52, a transmission filter 41, a reception filter 42, a power amplifier 61, and a low-noise amplifier 62.

The external terminal 10a is an antenna terminal to which the antenna 3 is connected. The external terminal 10b is an input terminal that is connected to an output portion (not illustrated) of the signal processing circuit 2 and inputs the transmission signal processed by the signal processing circuit 2 to the high-frequency module 1. The external terminal 10c is an output terminal that is connected to an input portion (not illustrated) of the signal processing circuit 2 and outputs the reception signal processed by the high-frequency module 1 to the input portion of the signal processing circuit 2. The external terminal 10d is a ground terminal for keeping the ground electrodes of the plurality of electronic components at a ground potential. The external terminal 10d is electrically connected to a ground outside the high-frequency module 1 and kept at the ground potential.

In the first embodiment, the phrase “A is connected to B” is not limited to the case where A is directly connected to B, and includes a case where A is indirectly connected to B via another electronic component. The phrase “A is connected to B” means that A is conductively (i.e., electrically) connected to B.

The switch 20 is, for example, an antenna switch. The switch 20 selects the connection destination of the external terminal 10a from among a plurality of filters (transmission filter 41 and reception filter 42 in the example of FIG. 1). The switch 20 is, for example, a switch IC (Integrated Circuit). The switch 20 is controlled by, for example, the signal processing circuit 2. The switch 20 includes a common terminal 20a and a plurality of (two in the example of FIG. 1) selection terminals 20b and 20c. The common terminal 20a is selectively connectable to at least one of the plurality of selection terminals 20b and 20c. The common terminal 20a is connected to the external terminal 10a. The selection terminal 20b is connected to an output portion 41b of the transmission filter 41 described later via the matching circuit 31. The selection terminal 20c is connected to an input portion 42a of the reception filter 42 described later via the matching circuit 32.

The transmission filter 41 has a pass band including a transmission band of a first communication band. The first communication band is, for example, an LB communication band. The transmission filter 41 includes an input portion 41a and the output portion 41b. The input portion 41a is connected to an output portion 61b of the power amplifier 61 via the matching circuit 51. The output portion 41b is connected to the selection terminal 20b of the switch 20 via the matching circuit 31. A signal (transmission signal) from the input portion 41a is input to the transmission filter 41. The input signal passes through the transmission filter 41 while being limited to a signal in the transmission band of the first communication band. The signal having passed through the transmission filter 41 is output from the output portion 41b.

The reception filter 42 has a pass band including a reception band of a second communication band. The second communication band is, for example, an MB or HB communication band. The pass band of the second communication band overlaps at least part of the frequency band of a harmonic component of the transmission signal in the first communication band. The “harmonic component of the transmission signal” is a signal having a frequency that is N times (N: integer of 2 or more) as high as the frequency of the transmission signal. The reception filter 42 includes the input portion 42a and an output portion 42b. The input portion 42a is connected to the selection terminal 20c of the switch 20 via the matching circuit 32. The output portion 42b is connected to an input portion 62a of the low-noise amplifier 62 via the matching circuit 52. A signal (reception signal) from the input portion 42a is input to the reception filter 42. The input signal passes through the reception filter 42 while being limited to a signal in the reception band of the second communication band. The signal having passed through the reception filter 42 is output from the output portion 42b.

The power amplifier 61 amplifies a signal (transmission signal) input from the signal processing circuit 2 to the high-frequency module 1 via the external terminal 10b. The power amplifier 61 is connected between the external terminal 10b and the transmission filter 41. The power amplifier 61 includes an input portion 61a and the output portion 61b. The input portion 61a is connected to the external terminal 10b. The output portion 61b is connected to the input portion 41a of the transmission filter 41 via the matching circuit 51. The power amplifier 61 amplifies the signal (transmission signal) input to the input portion 61a, and outputs the amplified signal from the output portion 61b.

The low-noise amplifier 62 amplifies an output signal (reception signal) from the reception filter 42. The low-noise amplifier 62 is connected between the external terminal 10c and the reception filter 42. The low-noise amplifier 62 includes the input portion 62a and an output portion 62b. The input portion 62a is connected to the output portion 42b of the reception filter 42 via the matching circuit 52. The output portion 62b is connected to the external terminal 10c. The low-noise amplifier 62 amplifies the signal (reception signal) input to the input portion 62a, and outputs the amplified signal from the output portion 62b.

The matching circuit 31 is a circuit for impedance matching between the selection terminal 20b of the switch 20 and the transmission filter 41. The matching circuit 31 is connected between the selection terminal 20b of the switch 20 and the transmission filter 41.

The matching circuit 32 is a circuit for impedance matching between the selection terminal 20c of the switch 20 and the reception filter 42. The matching circuit 32 is connected between the selection terminal 20c of the switch 20 and the reception filter 42.

The matching circuit 51 is a circuit for impedance matching between the transmission filter 41 and the power amplifier 61. The matching circuit 51 is connected between the transmission filter 41 and the power amplifier 61.

The matching circuit 52 is a circuit for impedance matching between the reception filter 42 and the low-noise amplifier 62. The matching circuit 52 is connected between the reception filter 42 and the low-noise amplifier 62.

### Operations of High-frequency Module

Operation during Transmission

During transmission in the high-frequency module 1, the common terminal 20a is connected to the selection terminal 20b in the switch 20. A transmission signal is input from the signal processing circuit 2 to the external terminal 10b. The transmission signal input to the external terminal 10b passes through the power amplifier 61, the matching circuit 51, the transmission filter 41, the matching circuit 31, the switch 20, and the external terminal 10a in this order, and is transmitted from the antenna 3.

Operation during Reception

During reception in the high-frequency module 1, the common terminal 20a is connected to the selection terminal 20c in the switch 20. A reception signal is received by the antenna 3. The reception signal received by the antenna 3 passes through the external terminal 10a, the switch 20, the matching circuit 32, the reception filter 42, the matching circuit 52, the low-noise amplifier 62, and the external terminal 10c in this order, and is output to the signal processing circuit 2.

### Example of Structure of High-frequency Module

As illustrated in FIG. 2, the high-frequency module 1 further includes the mounting board 70, a first resin member 71 (resin member), the metal members 72 and 73, a second resin member 74, and an external shield layer (not illustrated) in addition to the plurality of electronic components and the external terminals 10a to 10d described above. In the example of FIG. 2, the mounting board 70 is partially illustrated only in the range in which the transmission component 75 and the electronic component 76 are disposed.

The mounting board 70 is a board where the plurality of electronic components is disposed (mounted). The mounting board 70 has, for example, a rectangular flat-plate shape in a plan view in a thickness direction D1 of the mounting board 70. The mounting board 70 is, for example, a resin multilayer board. The mounting board 70 is not limited to the resin multilayer board and may be, for example, a printed wiring board, an LTCC (Low Temperature Co-fired Ceramics) board, or an HTCC (High Temperature Co-fired Ceramics) board.

The mounting board 70 has a first principal surface 70a and a second principal surface 70b. The first principal surface 70a and the second principal surface 70b are principal surfaces that face each other in the thickness direction D1 of the mounting board 70. The plurality of electronic components is disposed on the first principal surface 70a of the mounting board 70. In the example of FIG. 2, only the transmission component 75 and the electronic component 76 described later are illustrated among the plurality of electronic components. More specifically, a plurality of pad electrodes is provided to the first principal surface 70a of the mounting board 70. The plurality of electronic components is disposed on the first principal surface 70a of the mounting board 70 with their outer electrodes connected by the plurality of pad electrodes and solder. The plurality of external terminals 10a to 10d of the high-frequency module 1 is disposed on the second principal surface 70b of the mounting board 70. The plurality of pad electrodes is connected to the plurality of external terminals 10a to 10c via wiring electrodes (e.g., via electrodes and conductive layers) provided to the mounting board 70.

The mounting board 70 includes a ground layer. The ground layer is electrically connected to the external terminal 10d. The external terminal 10d is the ground terminal electrically connected to the ground outside the high-frequency module 1. The ground layer is connected to the external ground via the external terminal 10d, and the potential of the ground layer is kept at the ground potential. The ground layer is electrically connected to the ground electrodes of the plurality of electronic components.

The plurality of pad electrodes includes ground electrodes 70g connected to the ground layer.

The mounting board 70 is, for example, a board having a single side mounting structure in which the plurality of electronic components is mounted on the first principal surface 70a of the mounting board 70. In the example of FIG. 2, only the transmission component 75 and the electronic component 76 are illustrated among the plurality of electronic components.

The transmission component 75 is disposed on the first principal surface 70a of the mounting board 70. Among the plurality of electronic components, the transmission component 75 is an electronic component to be used for processing a transmission signal to be transmitted from the antenna 3, and is an electronic component provided to a transmission path between the external terminal 10b and the external terminal 10a. In the first embodiment, the transmission component 75 is any one of the power amplifier 61, the matching circuit 51, the transmission filter 41, and the matching circuit 31. In the example of FIG. 2, the transmission component 75 is assumed to be the power amplifier 61. A transmission signal in the first communication band flows through the transmission component 75. The transmission component 75 processes (e.g., amplifies) the transmission signal in the first transmission band. The transmission component 75 has, for example, a rectangular parallelepiped shape.

More specifically, the transmission component 75 includes a plurality of first outer electrodes (not illustrated) and a first component body 75a. The first component body 75a is a portion of the transmission component 75 other than the plurality of first outer electrodes, and includes a first circuit portion that controls the function of the transmission component 75. The first component body 75a has, for example, a rectangular parallelepiped shape. The first circuit portion is electrically connected to the plurality of first outer electrodes. Each of the plurality of first outer electrodes is electrically connected to any one of the plurality of pad electrodes on the mounting board 70. The plurality of first outer electrodes is provided to the back surface of the first component body 75a. The back surface of the first component body 75a is a principal surface of the first component body 75a that faces the mounting board 70.

The transmission component 75 has a top surface 75t and an outer peripheral surface 75s. The top surface 75t is a principal surface of the transmission component 75 (more specifically, the first component body 75a) opposite to the mounting board 70. The top surface 75t has, for example, a rectangular shape. The outer peripheral surface 75s is an outer peripheral surface of the transmission component 75 (more specifically, the first component body 75a) that surrounds the top surface 75t.

The electronic component 76 is disposed on the first principal surface 70a of the mounting board 70. The electronic component 76 is, for example, a reception component. Among the plurality of electronic components, the reception component is an electronic component to be used for processing a reception signal received by the antenna 3, and is an electronic component provided to a reception path between the external terminal 10c and the external terminal 10a. In the first embodiment, the reception component is any one of, for example, the matching circuit 32, the reception filter 42, the matching circuit 52, and the low-noise amplifier 62. In the example of FIG. 2, the electronic component 76 is assumed to be the low-noise amplifier 62. The electronic component 76 handles a reception signal in the second communication band (i.e., a reception signal in a frequency band that at least partially overlaps the frequency band of the harmonic component of the transmission signal generated by the transmission component 75). The electronic component 76 processes (e.g., amplifies) the reception signal in the second communication band.

More specifically, the electronic component 76 includes a second component body 76a and a plurality of second outer electrodes (not illustrated). The second component body 76a is a portion of the electronic component 76 other than the plurality of second outer electrodes. The second component body 76a includes a second circuit portion that controls the function of the electronic component 76. The second circuit portion is electrically connected to the plurality of second outer electrodes. The second component body 76a has, for example, a rectangular parallelepiped shape. The plurality of second outer electrodes is provided to the back surface of the second component body 76a. The back surface of the second component body 76a is a principal surface of the second component body 76a that faces the mounting board 70. Each of the plurality of second outer electrodes is electrically connected to any one of the plurality of pad electrodes on the mounting board 70.

The electronic component 76 is disposed, for example, to adjoin the transmission component 75. The phrase “A is disposed to adjoin B” means that no other electronic component is disposed between A and B. Therefore, in the plan view in the thickness direction D1 of the mounting board 70, no other electronic component is disposed between the transmission component 75 and the electronic component 76. However, the electronic component 76 need not be disposed to adjoin the transmission component 75. That is, another electronic component may be disposed between the electronic component 76 and the transmission component 75.

The first resin member 71 is made of a resin. The first resin member 71 is provided to the surface of at least one component out of the transmission component 75 and the electronic component 76 (transmission component 75 in the example of FIG. 2). Regarding the phrase “A is provided to the surface of B,” A may be provided to the entire surface of B or part of the surface of B. In the example of FIG. 2, the first resin member 71 is provided to the entire surface of the transmission component 75.

As described later, the metal members 72 and 73 are disposed on the surface of the first resin member 71. That is, the first resin member 71 is interposed between the transmission component 75 and the metal members 72 and 73. Thus, the first resin member 71 secures the spacing between the transmission component 75 and the metal members 72 and 73 to some degree. Since the first resin member 71 secures the spacing between the transmission component 75 and the metal members 72 and 73 to some degree, the noise attenuation function of the metal members 72 and 73 described later can be improved compared with a case where the metal members 72 and 73 are disposed directly on the surface of the transmission component 75.

The first resin member 71 includes atop surface portion 71t and an outer peripheral portion 71s. The top surface portion 71t is provided to the top surface 75t of the transmission component 75. The top surface portion 71t has, for example, a rectangular shape. In the example of FIG. 2, the top surface portion 71t is provided to the entire top surface 75t of the transmission component 75. The outer peripheral portion 71s is provided to the outer peripheral surface 75s of the transmission component 75. In the example of FIG. 2, the outer peripheral portion 71s is provided to the entire outer peripheral surface 75s of the transmission component 75.

The metal members 72 and 73 are members for blocking a harmonic component that is issued from the transmission component 75 and is a harmonic component of the transmission signal generated by the transmission component 75. The metal members 72 and 73 are made of a metal or alloy. The metal members 72 and 73 are disposed near at least one component out of the transmission component 75 and the electronic component 76 (transmission component 75 in the example of FIG. 2).

The phrase “the metal members 72 and 73 are disposed near the transmission component 75” means that, if the metal members 72 and 73 are not disposed between the transmission component 75 and the electronic component 76, the metal members 72 and 73 are provided to the surface of the transmission component 75 directly or indirectly with the first resin member 71 interposed between the metal members 72 and 73 and the transmission component 75. Regarding the phrase “the metal members 72 and 73 are disposed near the transmission component 75,” if the metal members 72 and 73 are disposed between the transmission component 75 and the electronic component 76, the metal members 72 and 73 may be provided to the surface of the transmission component 75 directly or indirectly with the first resin member 71 interposed between the metal members 72 and 73 and the transmission component 75, or need not be provided to the surface of the transmission component 75 directly or indirectly with the first resin member 71 interposed between the metal members 72 and 73 and the transmission component 75. That is, the metal members 72 and 73 in this case may be disposed at any location between the transmission component 75 and the electronic component 76. The phrase “A is disposed between B and C” means that, in the plan view of the mounting board 70 in the thickness direction D1, at least one of a plurality of line segments each connecting any point in the region of B and any point in the region of C passes through the region of A. In the example of FIG. 2, the metal members 72 and 73 are disposed on the surface of the first resin member 71.

The metal members 72 and 73 each have an electrical length that is a half or quarter of the wavelength of the harmonic component of the transmission signal flowing through the transmission component 75. That is, the metal members 72 and 73 in the first embodiment have different electrical lengths. The metal members 72 and 73 each have, for example, a linear shape (or a band shape).

More specifically, the metal member 72 has an electrical length that is a half of the wavelength of the harmonic component. The metal member 72 mainly blocks a signal of a frequency component corresponding to the half electrical length among the signals of the frequency components included in the harmonic component. The metal member 72 has a first end 72a and a second end 72b. In the metal member 72, the length between the first end 72a and the second end 72b along the metal member 72 is the electrical length that is a half of the harmonic component. The metal member 72 is disposed on the top surface portion 71t of the first resin member 71. That is, the metal member 72 is disposed at the top surface 75t of the transmission component 75 with the top surface portion 71t interposed therebetween. The first end 72a and the second end 72b of the metal member 72 are open ends and disposed on the top surface portion 71t of the first resin member 71. The metal member 72 is disposed so as to linearly connect the first end 72a and the second end 72b. The metal member 72 is disposed, for example, along one side (e.g., a long side) out of the four outer sides of the top surface portion 71t.

The metal member 73 has an electrical length that is a quarter of the wavelength of the harmonic component. The metal member 73 mainly blocks a signal of a frequency component corresponding to the quarter electrical length among the signals of the frequency components included in the harmonic component. The metal member 73 has a first end 73a and a second end 73b. In the metal member 73, the length between the first end 73a and the second end 73b along the metal member 73 is the electrical length that is a quarter of the harmonic component. The metal member 73 is disposed on at least the outer peripheral portion 71s out of the top surface portion 71t and the outer peripheral portion 71s of the first resin member 71. In the example of FIG. 2, the metal member 73 is disposed astride the top surface portion 71t and the outer peripheral portion 71s. The first end 73a of the metal member 73 is connected to the ground electrode 70g provided to the first principal surface 70a of the mounting board 70. The first end 73a is electrically connected to the ground layer of the mounting board 70 via the ground electrode 70g. That is, the first end 73a is electrically connected to the external ground via the ground layer. The second end 73b of the metal member 73 is an open end and disposed on the outer peripheral portion 71s or the top surface portion 71t of the first resin member 71. That is, the second end 73b is disposed at the outer peripheral surface 75s or the top surface 75t of the transmission component 75 with the first resin member 71 interposed therebetween. In the example of FIG. 2, the second end 73b is disposed on the top surface portion 71t of the first resin member 71. That is, the second end 73b is disposed at the top surface 75t of the transmission component 75 with the top surface portion 71t interposed therebetween.

The metal member 73 includes a first portion 73u and a second portion 73v.

The first portion 73u is a portion disposed on the outer peripheral portion 71s of the first resin member 71 (i.e., a portion disposed at the outer peripheral surface 75s of the transmission component 75 with the first resin member 71 interposed therebetween). One end of the first portion 73u is the first end 73a. The other end of the first portion 73u is connected to the other end of the second portion 73v described later. On the outer peripheral portion 71s of the first resin member 71, the first portion 73u linearly extends from the first end 73a to the top surface portion 71t of the first resin member 71 along the thickness direction of the transmission component 75 (i.e., the same direction as the thickness direction D1 of the mounting board 70).

The second portion 73v is a portion disposed on the top surface portion 71t of the first resin member 71 (i.e., a portion disposed at the top surface 75t of the transmission component 75 with the first resin member 71 interposed therebetween). One end of the second portion 73v is the second end 73b. The other end of the second portion 73v is connected to the other end of the first portion 73u. The second portion 73v linearly extends from the other end of the second portion 73v to the second end 73b. In the example of FIG. 2, the second portion 73v extends parallel to one side (e.g., the long side) out of the four outer sides of the top surface portion 71t of the first resin member 71.

That is, the metal member 73 linearly extends from the first end 73a to the top surface portion 71t on the outer peripheral portion 71s of the first resin member 71 along the thickness direction of the transmission component 75, bends at the boundary between the outer peripheral portion 71s and the top surface portion 71t, and linearly extends to the second end 73b along the top surface portion 71t.

The second resin member 74 is a resin member for sealing the plurality of electronic components disposed on the first principal surface 70a of the mounting board 70 and the metal members 72 and 73. The second resin member 74 is provided to the first principal surface 70a of the mounting board 70 so as to cover the plurality of electronic components and the metal members 72 and 73. In the example of FIG. 2, only a portion of the second resin member 74 that covers the transmission component 75, the electronic component 76, the first resin member 71, and the metal members 72 and 73 is illustrated.

The external shield layer (not illustrated) is a member for electromagnetically shielding the inside and outside of the high-frequency module 1. The external shield layer is made of a conductive member (e.g., copper). The external shield layer is provided so as to cover the surface of the second resin member 74. The surface of the second resin member 74 includes a top surface 74t and an outer peripheral surface of the second resin member 74. The top surface 74t of the second resin member 74 is a principal surface of the second resin member 74 opposite to the mounting board 70. The outer peripheral surface of the second resin member 74 is an outer peripheral surface of the second resin member 74 that surrounds the top surface 74t. The external shield layer is electrically connected to the ground layer of the mounting board 70 at the outer peripheral surface of the mounting board 70. Thus, the potential of the external shield layer is kept at the ground potential via the ground layer.

### Noise Attenuation Function of Metal Members 72 and 73

The noise attenuation function of the metal members 72 and 73 is described. When a transmission signal flows through the transmission component 75, a harmonic component of the transmission signal is issued from the transmission component 75 to the surrounding space. A reception signal in a frequency band that at least partially overlaps the frequency band of the harmonic component flows through the electronic component 76. Therefore, the harmonic component issued from the transmission component 75 may be superimposed as noise on the reception signal flowing through the electronic component 76. However, the harmonic component issued from the transmission component 75 is blocked by the metal members 72 and 73 disposed near the transmission component 75. This blocking reduces propagation of the harmonic component to the surroundings of the transmission component 75. Thus, the superimposition of the harmonic component as noise on the reception signal flowing through the electronic component 76 is reduced. That is, the noise superimposed on the reception signal flowing through the electronic component 76 is attenuated.

### Advantages

As described above, the high-frequency module 1 according to the first embodiment includes the mounting board 70, the transmission component 75, the electronic component 76, and the metal members 72 and 73. The transmission component 75 is disposed on the mounting board 70. The electronic component 76 is disposed on the mounting board 70, and handles a signal in a frequency band that at least partially overlaps the frequency band of the harmonic component of the transmission signal generated by the transmission component 75. The metal members 72 and 73 are disposed near at least one component out of the transmission component 75 and the electronic component 76, and each have the electrical length that is a half or quarter of the wavelength of the harmonic component.

With this structure, the metal members 72 and 73 can improve the isolation between the transmission component 75 and the electronic component 76. Thus, the metal members 72 and 73 can suppress the superimposition of the harmonic component as noise on the signal flowing through the electronic component 76.

In the high-frequency module 1 according to the first embodiment, the transmission component 75 is the power amplifier 61. With this structure, the metal members 72 and 73 can improve isolation between the power amplifier 61 (i.e., the electronic component that issues the harmonic component most intensely) and the electronic component 76.

The high-frequency module 1 according to the first embodiment further includes the first resin member 71 (resin member). The first resin member 71 is provided to the surface of the at least one component (transmission component 75 in the first embodiment). The metal members 72 and 73 are disposed on the surface of the first resin member 71. With this structure, the degree of freedom in terms of the disposition of the metal members 72 and 73 can be improved. Further, the spacing between the metal members 72 and 73 and the at least one component can be secured. Thus, the metal members 72 and 73 can further improve the isolation between the transmission component 75 and the electronic component 76. That is, the noise attenuation function of the metal members 72 and 73 can further be improved.

In the high-frequency module 1 according to the first embodiment, the metal member 72 has the electrical length that is a half of the wavelength of the harmonic component. The metal member 72 is a linear member with both the ends 72a and 72b open. With this structure, both the ends 72a and 72b of the metal member 72 having the electrical length that is a half of the wavelength of the harmonic component can be open. Thus, the degree of freedom in terms of the disposition positions of the metal members 72 and 73 can be improved.

In the high-frequency module 1 according to the first embodiment, the metal member 73 has the electrical length that is a quarter of the wavelength of the harmonic component. The metal member 73 is a linear member with the first end 73a (one end) connected to the ground electrode 70g provided to the mounting board 70. With this structure, the noise attenuation effect of the metal member 73 can be exerted effectively.

In the high-frequency module 1 according to the first embodiment, the metal member 73 includes the first portion 73u. The first portion 73u is disposed on the outer peripheral surface of at least one component out of the transmission component 75 and the electronic component 76 (transmission component 75 in the first embodiment) indirectly with the first resin member 71 interposed therebetween. The first portion 73u linearly extends along the thickness direction D1 of the at least one component. With this structure, the noise attenuation function of the metal member 73 having the electrical length that is a quarter of the wavelength of the harmonic component can be exerted effectively.

The high-frequency module 1 according to the first embodiment includes the plurality of metal members 72 and 73. With this structure, the noise attenuation effect of the metal members 72 and 73 can be improved.

In the high-frequency module 1 according to the first embodiment, the plurality of metal members 72 and 73 includes two or more metal members 72 and 73 having different electrical lengths. With this structure, a plurality of frequency components included in the harmonic component (i.e., a plurality of frequency components corresponding to the different electrical lengths) can be blocked.

The communication device 100 according to the first embodiment includes the high-frequency module 1 and the signal processing circuit 2. The signal processing circuit 2 is connected to the high-frequency module 1, and performs signal processing on a high-frequency signal. With this structure, the communication device 100 having the advantages of the high-frequency module 1 can be provided.

### MODIFICATIONS

Modifications of the high-frequency module 1 according to the first embodiment are described. In the following description, description of the same structure as in the first embodiment may be omitted and structures different from that in the first embodiment may be described mainly. The following modifications may be carried out in combination.

### 9-1 First Modification

In the first embodiment, the metal members 72 and 73 each have the linear shape. However, the metal member 72 may be curved in, for example, an S-shape or an arc shape, or may be bent. Similarly, each of the first portion 73u and the second portion 73v of the metal member 73 may be curved in, for example, an S-shape or an arc shape, or may be bent.

### 9-2 Second Modification

In the first embodiment, the metal member 72 has the electrical length that is a half of the wavelength of the harmonic component, and the metal member 73 has the electrical length that is a quarter of the wavelength of the harmonic component. However, at least one of the metal members 72 and 73 may be provided. That is, advantages similar to those of the first embodiment can be attained even in the case where only the metal member 72 or 73 is provided out of the metal members 72 and 73.

### 9-3 Third Modification

In the first embodiment, the metal members 72 and 73 are disposed near the transmission component 75. However, the metal members 72 and 73 may be disposed near the electronic component 76 instead of being disposed near the transmission component 75. In this case, the first resin member 71 is provided to the surface of the electronic component 76 instead of being provided to the surface of the transmission component 75. The metal members 72 and 73 are disposed at the surface of the electronic component 76 with the first resin member 71 interposed between the metal members 72 and 73 and the electronic component 76. Also in this case, advantages similar to those of the first embodiment can be attained.

The metal members 72 and 73 may be disposed near the electronic component 76 as well as being disposed near the transmission component 75. In this case, the first resin member 71 is provided to the surface of the electronic component 76 as well as being provided to the surface of the transmission component 75. The metal members 72 and 73 are disposed at the surface of the electronic component 76 with the first resin member 71 interposed between the metal members 72 and 73 and the electronic component 76 as well as being disposed near the transmission component 75. Also in this case, advantages similar to those of the first embodiment can be attained.

### 9-4 Fourth Modification

In the first embodiment, the metal members 72 and 73 are disposed near the transmission component 75. However, the metal members 72 and 73 may be disposed between the transmission component 75 and the electronic component 76. In this case, the metal members 72 and 73 may be kept out of contact with the surfaces of both the transmission component 75 and the electronic component 76. Also in this case, advantages similar to those of the first embodiment can be attained. In the fourth modification, the metal members can improve the isolation between the transmission component 75 and the electronic component 76 similarly to the first embodiment.

### 9-5 Fifth Modification

In the first embodiment, the electronic component 76 is the reception component. However, the electronic component 76 may be a transmission component. In this case, the electronic component 76 that is the transmission component is a transmission component through which a transmission signal flows in a frequency band that at least partially overlaps the frequency band of the harmonic component of the transmission signal flowing through the transmission component 75.

In a high-frequency module 1 according to a fifth modification, it is assumed, for example, that the high-frequency module 1 according to the first embodiment further includes another transmission filter, another matching circuit, and another power amplifier compatible with another communication band including a pass band that at least partially overlaps the pass band of the first communication band. The electronic component 76 that is the transmission component in the fifth modification is any one of, for example, a plurality of electronic components (including the other power amplifier, the other matching circuit, and the other transmission filter) provided to a transmission path that is provided with the other power amplifier, the other matching circuit, and the other transmission filter.

The fifth modification has an advantage in that the superimposition of the harmonic component issued from the transmission component 75 as noise on the transmission signal flowing through the electronic component 76 that is the transmission component can be reduced.

### 9-6 Sixth Modification

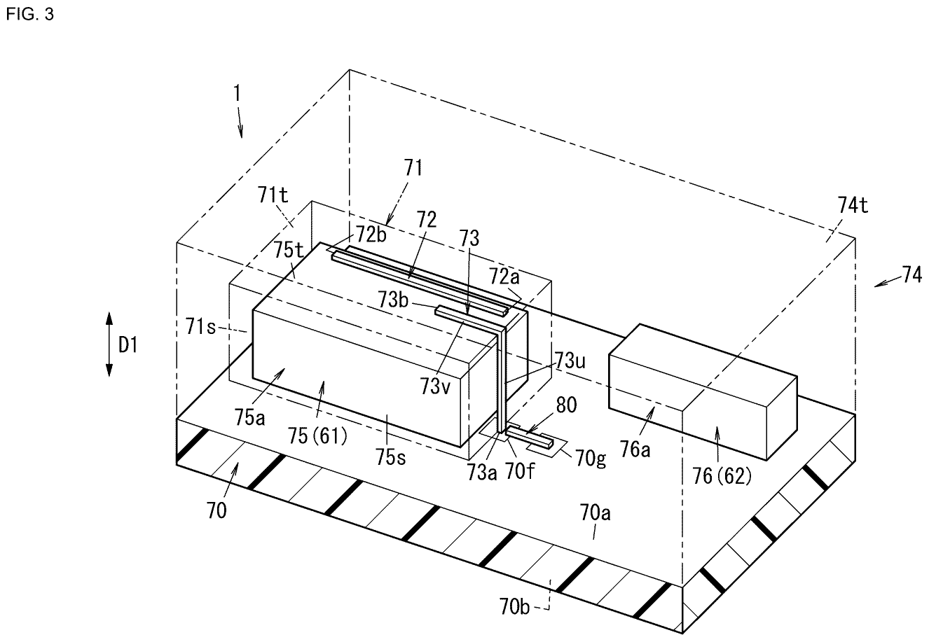

As illustrated in FIG. 3, in a sixth modification, the first end 73a of the metal member 73 in the first embodiment is connected to the ground electrode 70g on the mounting board 70 via a circuit 80. The circuit 80 is a circuit for adjusting (e.g., reducing) the electrical length of the metal member 73. The circuit 80 includes at least one of an inductor and a capacitor. The circuit 80 is constructed as one packaged circuit component (e.g., SMD (Surface Mount Device)). The circuit 80 has an input end and an output end. The input end of the circuit 80 is connected to the first end 73a of the metal member 73. In the example of FIG. 3, the input end of the circuit 80 is connected to the first end 73a of the metal member 73 via a pad electrode 70f provided to the first principal surface 70a of the mounting board 70. The output end of the circuit 80 is connected to the ground electrode 70g provided to the first principal surface 70a of the mounting board 70.

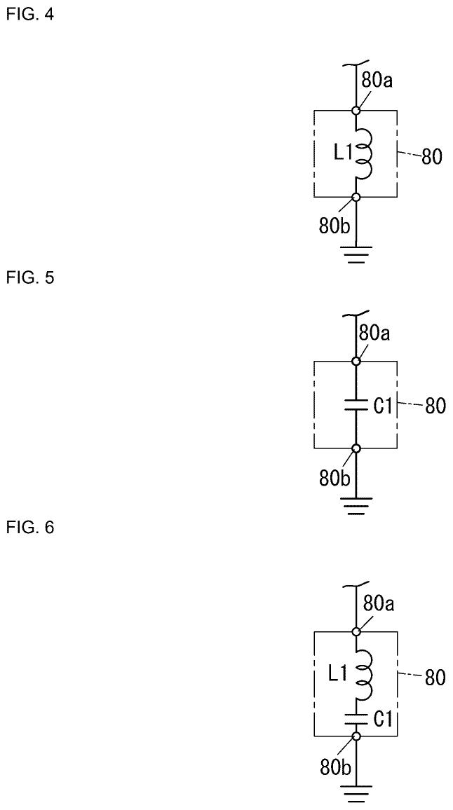

FIGS. 4 to 7 illustrate variations of the circuit structure of the circuit 80.

The circuit 80 illustrated in FIG. 4 includes an input end 80a that is the input end described above, an output end 80b that is the output end described above, and an inductor L1. The input end 80a is connected to the first end 73a of the metal member 73. The output end 80b is connected to the ground via the ground electrode 70g on the mounting board 70. The inductor L1 is connected in series between the input end 80a and the output end 80b.

The circuit 80 illustrated in FIG. 5 includes the input end 80a that is the input end described above, the output end 80b that is the output end described above, and a capacitor C1. The input end 80a is connected to the first end 73a of the metal member 73. The output end 80b is connected to the ground via the ground electrode 70g on the mounting board 70. The capacitor C1 is connected in series between the input end 80a and the output end 80b.

The circuit 80 illustrated in FIG. 6 includes the input end 80a that is the input end described above, the output end 80b that is the output end described above, the inductor L1, and the capacitor C1. The input end 80a is connected to the first end 73a of the metal member 73. The output end 80b is connected to the ground via the ground electrode 70g on the mounting board 70. The inductor L1 and the capacitor C1 are connected in series between the input end 80a and the output end 80b while being connected in series to each other.

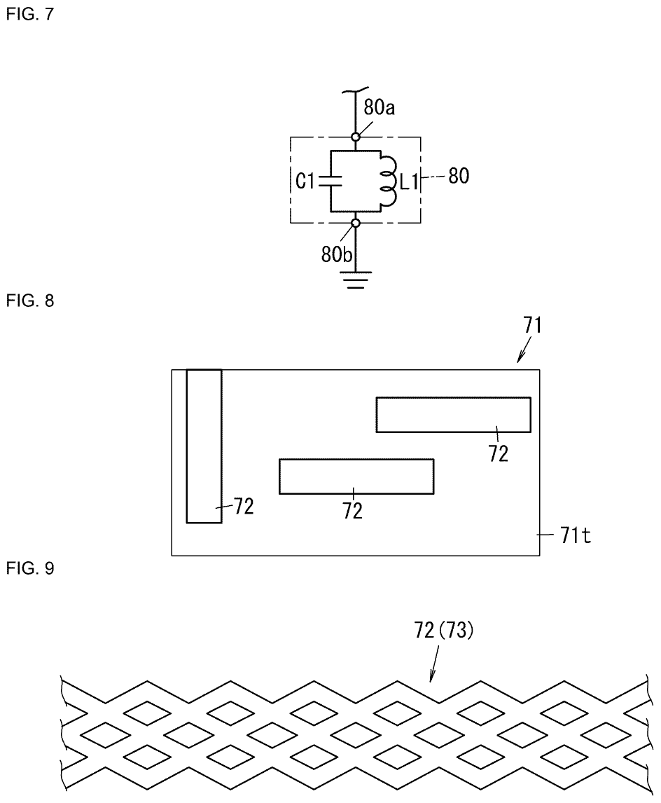

The circuit 80 illustrated in FIG. 7 includes the input end 80a that is the input end described above, the output end 80b that is the output end described above, the inductor L1, and the capacitor C1. The input end 80a is connected to the first end 73a of the metal member 73. The output end 80b is connected to the ground via the ground electrode 70g on the mounting board 70. The inductor L1 and the capacitor C1 are connected in series between the input end 80a and the output end 80b while being connected parallel to each other.

As described above, in the sixth modification, the first end 73a (one end) of the metal member 73 is connected to the ground electrode 70g via the circuit 80 including at least one of the inductor L1 and the capacitor C1. With this structure, the electrical length of the metal member 73 can be reduced. As a result, the metal member 73 can be downsized.

In the sixth modification, the circuit 80 is constructed as the SMD. However, the circuit 80 may be provided inside the mounting board 70 or to the first principal surface 70a using a wiring electrode provided inside the mounting board 70 or to the first principal surface 70a.

### 9-7 Seventh Modification

In the first embodiment, the high-frequency module 1 includes the plurality of metal members 72 and 73 having different electrical lengths. As illustrated in FIG. 8, however, the high-frequency module 1 may include a plurality of metal members having the same electrical length. In the example of FIG. 8, the high-frequency module 1 includes three metal members 72 each having an electrical length that is a half of the wavelength of the harmonic component. In the example of FIG. 8, the three metal members 72 are disposed on the top surface portion 71t of the first resin member 71. For example, one metal member 72 out of the three metal members 72 is disposed along one side (e.g., a short side) out of the four outer sides of the top surface portion 71t. Two metal members 72 out of the three metal members 72 are disposed along another side (e.g., the long side) out of the four outer sides of the top surface portion 71t.

As described above, in the seventh modification, the plurality of metal members of the high-frequency module 1 includes two or more metal members (e.g., the metal members 72) having the same electrical length. With this structure, the function of blocking a specific frequency component included in the harmonic component (frequency component corresponding to the same electrical length) can be enhanced.

### 9-8 Eighth Modification

As illustrated in FIG. 9, at least one metal member out of the metal members 72 and 73 in an eighth modification is formed in a mesh pattern. More specifically, the at least one metal member has a band shape outside, and is formed in the mesh pattern inside.

### Second Embodiment

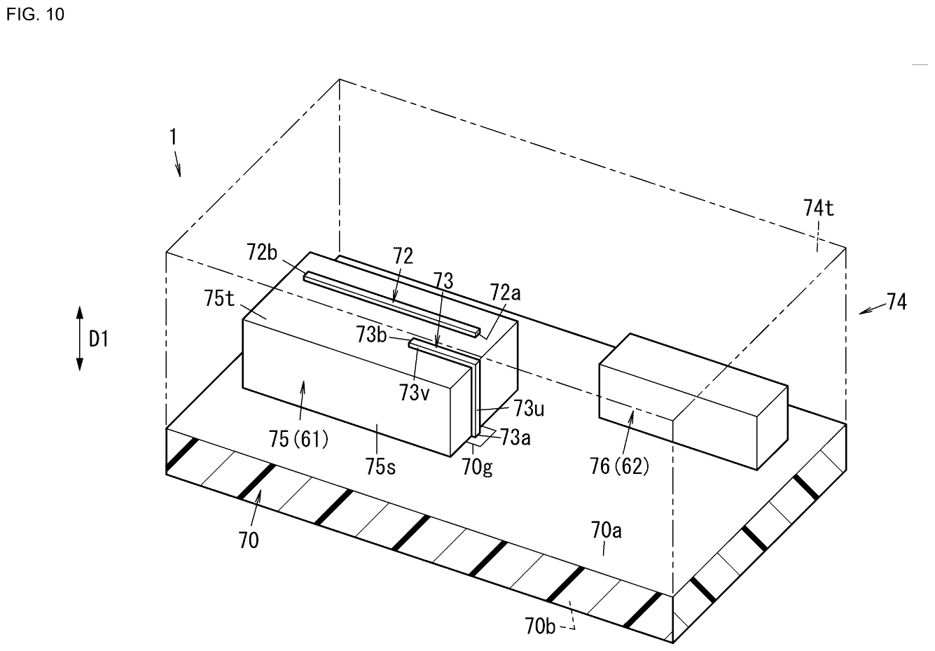

A high-frequency module 1 according to a second embodiment is described with reference to FIG. 10. In the following description, description of the same structure as in the first embodiment may be omitted and a structure different from that in the first embodiment may be described mainly.

The high-frequency module 1 according to the second embodiment is similar to the high-frequency module 1 according to the first embodiment except for the difference in that the first resin member 71 is omitted. The second embodiment is described in detail below.

### Structure

In the second embodiment, the first resin member 71 is omitted as described above compared with the first embodiment. Thus, the metal members 72 and 73 are disposed on the transmission component 75 while being in contact with the surface of the transmission component 75. In the second embodiment, the metal members 72 and 73 are disposed near the transmission component 75 by being disposed on the transmission component 75 while being in contact with the surface of the transmission component 75.

More specifically, the metal member 72 is disposed on the top surface 75t of the transmission component 75. That is, the first end 72a and the second end 72b of the metal member 72 are disposed on the top surface 75t of the transmission component 75. The metal member 72 is disposed so as to, for example, linearly connect the first end 72a and the second end 72b. The metal member 72 is disposed, for example, along one side (e.g., a long side) out of the four outer sides of the top surface 75t.

The metal member 73 is disposed on at least the outer peripheral surface 75s out of the top surface 75t and the outer peripheral surface 75s of the transmission component 75. In the example of FIG. 10, the metal member 73 is disposed astride the top surface 75t and the outer peripheral surface 75s of the transmission component 75. The first end 73a of the metal member 73 is connected to the ground electrode 70g provided to the first principal surface 70a of the mounting board 70. The first end 73a is electrically connected to the ground layer of the mounting board 70 via the ground electrode 70g. That is, the first end 73a is electrically connected to the external ground via the ground layer. The second end 73b of the metal member 73 is disposed on the outer peripheral surface 75s or the top surface 75t of the transmission component 75. In the example of FIG. 10, the second end 73b is disposed on the top surface 75t of the transmission component 75. That is, the metal member 73 linearly extends from the first end 73a to the top surface 75t on the outer peripheral surface 75s of the transmission component 75 along the thickness direction of the transmission component 75, bends at the boundary between the outer peripheral surface 75s and the top surface 75t, and linearly extends to the second end 73b along the top surface 75t.

More specifically, the metal member 73 includes the first portion 73u and the second portion 73v.

The first portion 73u is a portion disposed on the outer peripheral surface 75s of the transmission component 75. One end of the first portion 73u is the first end 73a. The other end of the first portion 73u is connected to the other end of the second portion 73v described later. On the outer peripheral surface 75s of the transmission component 75, the first portion 73u linearly extends from the first end 73a to the top surface 75t of the transmission component 75 along the thickness direction of the transmission component 75 (i.e., the same direction as the thickness direction D1 of the mounting board 70).

The second portion 73v is a portion disposed on the top surface 75t of the transmission component 75. One end of the second portion 73v is the second end 73b. The other end of the second portion 73v is connected to the other end of the first portion 73u. The second portion 73v linearly extends from the other end of the second portion 73v to the second end 73b. In the example of FIG. 2, the second portion 73v extends parallel to one side (e.g., the long side) out of the four outer sides of the top surface 75t of the transmission component 75.

### 2 Advantages

The high-frequency module 1 according to the second embodiment has advantages similar to those of the high-frequency module 1 according to the first embodiment in terms of the same structural parts as those of the high-frequency module 1 according to the first embodiment.

In the high-frequency module 1 according to the second embodiment, the metal members 72 and 73 are disposed in contact with at least one component out of the transmission component 75 and the electronic component 76 (transmission component 75 in the second embodiment). With this structure, an increase in the size of the component (i.e., the at least one component) where the metal members 72 and 73 are disposed can be suppressed.

In the high-frequency module 1 according to the second embodiment, the metal member 73 includes the first portion 73u. The first portion 73u is disposed directly on the outer peripheral surface of at least one component out of the transmission component 75 and the electronic component 76 (transmission component 75 in the second embodiment). The first portion 73u linearly extends along the thickness direction of the at least one component (same direction as the thickness direction D1). With this structure, the noise attenuation function of the metal member 73 having the quarter electrical length can be exerted effectively.

Although the first and second embodiments and the modifications thereof have been described above, the first and second embodiments and the modifications thereof may be carried out in combination.

### Aspects

The following aspects are disclosed herein.

A high-frequency module (1) according to a first aspect includes a mounting board (70), a transmission component (75), an electronic component (76), and a metal member (72, 73). The transmission component (75) is disposed on the mounting board (70). The electronic component (76) is disposed on the mounting board (70), and handles a signal in a frequency band that at least partially overlaps a frequency band of a harmonic component of a transmission signal generated by the transmission component (75). The metal member (72, 73) is disposed near at least one component out of the transmission component (75) and the electronic component (76), and has an electrical length that is a half or a quarter of a wavelength of the harmonic component.

With this structure, the metal member (72, 73) can improve isolation between the transmission component (75) and the electronic component (76). Thus, the metal member (72, 73) can suppress superimposition of the harmonic component as noise on the signal flowing through the electronic component (76).

In the high-frequency module (1) according to a second aspect, in the first aspect, the transmission component (75) is a power amplifier (61).

With this structure, the metal member (72, 73) can improve isolation between the power amplifier (61) (i.e., the electronic component that issues the harmonic component most intensely) and the electronic component (76).

The high-frequency module (1) according to a third aspect further includes a resin member (71) in the first or second aspect. The resin member (71) is provided to a surface of the at least one component. The metal member (72, 73) is disposed on a surface of the resin member (71).

With this structure, the degree of freedom in terms of the disposition of the metal member (72, 73) can be improved. Further, the spacing between the metal member (72, 73) and the at least one component can be secured. Thus, the metal member (72, 73) can further improve the isolation between the transmission component (75) and the electronic component (76).

In the high-frequency module (1) according to a fourth aspect, in the first or second aspect, the metal member (72, 73) is disposed in contact with the at least one component.

With this structure, an increase in the size of the component (at least one component) where the metal member (72, 73) is disposed can be suppressed.

In the high-frequency module (1) according to a fifth aspect, in the third or fourth aspect, the metal member (72, 73) has an electrical length that is a half of the wavelength of the harmonic component. The metal member (72) is a linear member with both ends (72a, 72b) open.

With this structure, both the ends (72a, 72b) of the metal member (72) having the electrical length that is a half of the wavelength of the harmonic component can be open. Thus, the degree of freedom in terms of the disposition position of the metal member (72, 73) can be improved.

In the high-frequency module (1) according to a sixth aspect, in the third or fourth aspect, the metal member (72, 73) has an electrical length that is a quarter of the wavelength of the harmonic component. The metal member (73) is a linear member connected to a ground electrode (70g) provided to the mounting board (70).

With this structure, the noise attenuation effect of the metal member (73) can be exerted effectively.

In the high-frequency module (1) according to a seventh aspect, in the sixth aspect, the metal member (73) includes a first portion (73u) disposed on an outer peripheral surface of the at least one component directly or indirectly with a resin member (71) interposed therebetween. The first portion (73u) linearly extends along a thickness direction (D1) of the at least one component.

With this structure, the noise attenuation function of the metal member (73) having the quarter electrical length can be exerted effectively.

The high-frequency module (1) according to an eighth aspect includes a plurality of metal members (72, 73) including the metal member (72, 73) in any one of the first to seventh aspects.

With this structure, the noise attenuation effect of the metal members (72, 73) can be improved.

In the high-frequency module (1) according to a ninth aspect, in the eighth aspect, the plurality of metal members includes two or more metal members (72, 73) having different electrical lengths.

With this structure, a plurality of frequency components included in the harmonic component (plurality of frequency components corresponding to the different electrical lengths) can be blocked.

In the high-frequency module (1) according to a tenth aspect, in the eighth or ninth aspect, the plurality of metal members includes two or more metal members (72) having the same electrical length.

With this structure, the function of blocking a specific frequency component included in the harmonic component (frequency component corresponding to the same electrical length) can be enhanced.

In the high-frequency module (1) according to an eleventh aspect, in the sixth or seventh aspect, one end (73a) of the metal member (73) is connected to the ground electrode (70g) via a circuit (80). The circuit (80) includes at least one of an inductor (L1) and a capacitor (C1).

With this structure, the electrical length of the metal member (73) can be adjusted (e.g., reduced). When the electrical length of the metal member (73) is reduced, the metal member (73) can be downsized.

In the high-frequency module (1) according to a twelfth aspect, in any one of the first to eleventh aspects, the metal member (72, 73) is disposed between the transmission component (75) and the electronic component (76).

With this structure, the metal member (72, 73) can improve the isolation between the transmission component (75) and the electronic component (76).

A communication device according to a thirteenth aspect includes the high-frequency module (1) according to any one of the first to twelfth aspects and a signal processing circuit (2). The signal processing circuit (2) is connected to the high-frequency module (1), and performs signal processing on a high-frequency signal.

With this structure, the communication device (100) having the advantages of the high-frequency module (1) can be provided.

What is claimed is:

1. A high-frequency module comprising:
a mounting board;
a transmission component on the mounting board;
an electronic component that is on the mounting board and is configured to handle a signal in a frequency band that at least partially overlaps a frequency band of a harmonic component of a transmission signal generated by the transmission component; and
a metal member that is near at least one component out of the transmission component and the electronic component and has an electrical length that is a half or a quarter of a wavelength of the harmonic component.

2. The high-frequency module according to claim 1, wherein
the transmission component is a power amplifier.

3. The high-frequency module according to claim 1, further comprising:
a resin member at a surface of the at least one component, wherein
the metal member is on a surface of the resin member.

4. The high-frequency module according to claim 1, wherein
the metal member is in contact with the at least one component.

5. The high-frequency module according to claim 3, wherein
the metal member has an electrical length that is a half of the wavelength of the harmonic component, and is a linear member with both ends open.

6. The high-frequency module according to claim 3, wherein
the metal member has an electrical length that is a quarter of the wavelength of the harmonic component, and is a linear member with one end connected to a ground electrode that is at the mounting board.

7. The high-frequency module according to claim 6, wherein
the metal member includes a first portion on an outer peripheral surface of the at least one component directly or with a resin member interposed therebetween, and
the first portion linearly extends along a thickness direction of the at least one component.

8. The high-frequency module according to claim 1, further comprising:
a plurality of metal members including the metal member.

9. The high-frequency module according to claim 8, wherein
the plurality of metal members includes two or more metal members having different electrical lengths.

10. The high-frequency module according to claim 8, wherein
the plurality of metal members includes two or more metal members having the same electrical length.

11. The high-frequency module according to claim 6, wherein
the one end of the metal member is connected to the ground electrode via a circuit including at least one of an inductor and a capacitor.

12. The high-frequency module according to claim 1, wherein
the metal member is between the transmission component and the electronic component.

13. A communication device comprising:
the high-frequency module according to claim 1; and
a signal processing circuit that is connected to the high-frequency module and is configured to perform signal processing on a high-frequency signal.

14. The high-frequency module according to claim 4, wherein
the metal member has an electrical length that is a half of the wavelength of the harmonic component, and is a linear member with both ends open.

15. The high-frequency module according to claim 4, wherein
the metal member has an electrical length that is a quarter of the wavelength of the harmonic component, and is a linear member with one end connected to a ground electrode that is at the mounting board.

16. The high-frequency module according to claim 2, further comprising:
a plurality of metal members including the metal member.

17. The high-frequency module according to claim 3, further comprising:
a plurality of metal members including the metal member.

18. The high-frequency module according to claim 2, wherein
the metal member is between the transmission component and the electronic component.

19. The high-frequency module according to claim 3, wherein
the metal member is between the transmission component and the electronic component.

20. A communication device comprising:
the high-frequency module according to claim 2; and
a signal processing circuit that is connected to the high-frequency module and is configured to perform signal processing on a high-frequency signal.
